(19) United States
(12) Patent Application Publication
(10) Pub. No.: US 2013/0217243 A1
(43) Pub. Date: Aug. 22, 2013

(54) DOPING OF DIELECTRIC LAYERS

(71) Applicants: Brian S. Underwood, Santa Clara, CA (US); Nitin K. Ingle, San Jose, CA (US); Abhijit Basu Mallick, Palo Alto, CA (US)

(72) Inventors: Brian S. Underwood, Santa Clara, CA (US); Nitin K. Ingle, San Jose, CA (US); Abhijit Basu Mallick, Palo Alto, CA (US)

(73) Assignee: Applied Materials, Inc., Santa Clara, CA (US)

(21) Appl. No.: 13/590,761

(22) Filed: Aug. 21, 2012

Related U.S. Application Data
(60) Provisional application No. 61/536,380, filed on Sep. 19, 2011.
(60) Provisional application No. 61/532,708, filed on Sep. 9, 2011.
(60) Provisional application No. 61/550,755, filed on Oct. 24, 2011.
(60) Provisional application No. 61/567,738, filed on Dec. 7, 2011.

(51) Int. Cl. H01L 21/02

(52) U.S. Cl. CPC H01L 21/02356
USPC 438/783

(57) ABSTRACT

Methods are described for forming and treating a flowable silicon-carbon-and-nitrogen-containing layer on a semiconductor substrate. The silicon and carbon constituents may come from a silicon-and-carbon-containing precursor while the nitrogen may come from a nitrogen-containing precursor that has been activated to speed the reaction of the nitrogen with the silicon-and-carbon-containing precursor at lower deposition temperatures. The initially-flowable silicon-carbon-and-nitrogen-containing layer is ion implanted to increase etch tolerance, prevent shrinkage, adjust film tension and/or adjust electrical characteristics. Ion implantation may also remove components which enabled the flowability, but are no longer needed after deposition. Some treatments using ion implantation have been found to decrease the evolution of properties of the film upon exposure to atmosphere.

### CROSS-REFERENCES TO RELATED APPLICATIONS

This application claims the benefit of U.S. Provisional Application No. 61/536,380, filed Sep. 19, 2011, and titled “FLOWABLE SILICON-AND-CARBON-CONTAINING LAYERS FOR SEMICONDUCTOR PROCESSING.” This application also claims the benefit of U.S. Provisional Application No. 61/532,708 by Mallick et al, filed Sep. 9, 2011 and titled “FLOWABLE SILICON-CARBON-NITROGEN LAYERS FOR SEMICONDUCTOR PROCESSING.” This application also claims the benefit of U.S. Provisional Application No. 61/550,755 by Underwood et al, filed Oct. 24, 2011 and titled “TREATMENTS FOR DECREASING ETCH RATES AFTER FLOWABLE DEPOSITION OF SILICON-CARBON-AND-NITROGEN-CONTAINING LAYERS.” This application also claims the benefit of U.S. Provisional Application No. 61/567,738 by Underwood et al, filed Dec. 7, 2011 and titled “DOPING OF DIELECTRIC LAYERS.” Each of the above U.S. Provisional Applications is incorporated herein in its entirety for all purposes.

### BACKGROUND OF THE INVENTION

Semiconductor device geometries have dramatically decreased in size since their introduction several decades ago. Modern semiconductor fabrication equipment routinely produce devices with 45 nm, 32 nm, and 28 nm feature sizes, and new equipment is being developed and implemented to make devices with even smaller geometries. The decreasing feature sizes result in structural features on the device having decreased width. The widths of gaps and trenches on the device narrow such that filling the gap with dielectric material becomes more challenging. The depositing dielectric material is prone to clog at the top before the gap completely fills, producing a void or seam in the middle of the gap.

Over the years, many techniques have been developed to avoid having dielectric material clog the top of a gap, or to “heal” the void or seam that has been formed. One approach has been to start with flowable material that may be applied in a liquid phase to a spinning substrate surface (e.g., SOG deposition techniques). The flowable material can flow into and fill very small substrate gaps without forming voids or weak seams. The flowable material may contain silicon, carbon, oxygen and hydrogen. The flowable material is then cured to remove carbon and hydrogen thereby forming solid silicon oxide within the gaps.

The utility of gapfill silicon oxide often lies in its ability to electronically isolate adjacent transistors. Some process steps may benefit from the development of alternative materials which can still fill narrow gaps but possess low etch rates compared to silicon and/or silicon oxide. This and other needs are addressed in the present application.

### BRIEF SUMMARY OF THE INVENTION

Methods are described for forming and treating a flowable silicon-carbon-and-nitrogen-containing layer on a semiconductor substrate. The silicon and carbon constituents may come from a silicon-and-carbon-containing precursor while the nitrogen may come from a nitrogen-containing precursor that has been activated to speed the reaction of the nitrogen with the silicon-and-carbon-containing precursor at lower deposition temperatures. The initially-flowable silicon-carbon-and-nitrogen-containing layer is ion implanted to increase etch tolerance, prevent shrinkage, adjust film tension and/or adjust electrical characteristics. Ion implantation may also remove components which enabled the flowability, but are no longer needed after deposition. Some treatments using ion implantation have been found to decrease the evolution of properties of the film upon exposure to atmosphere.

Embodiments of the invention include methods of forming a silicon-carbon-and-nitrogen-containing layer on a semiconductor substrate. The methods include forming an as-deposited silicon-carbon-and-nitrogen-containing layer on the semiconductor substrate in a substrate processing region. The silicon-carbon-and-nitrogen-containing layer is initially flowable during deposition. The methods further include a subsequent step of ion implanting the as-deposited silicon-carbon-and-nitrogen-containing layer to form an ion-implanted silicon-carbon-and-nitrogen-containing layer.

Additional embodiments and features are set forth in part in the description that follows, and in part will become apparent to those skilled in the art upon examination of the specification or may be learned by the practice of the invention. The features and advantages of the invention may be realized and attained by means of the instrumentalities, combinations, and methods described in the specification.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components. In some instances, a sublabel is associated with a reference numeral and follows a hyphen to denote one of multiple similar components. When reference is made to a reference numeral without specification to an existing sublabel, it is intended to refer to all such multiple similar components.

FIG. 1 is a flowchart illustrating selected steps in a method of forming a silicon-carbon-and-nitrogen-containing dielectric layer on a substrate according to embodiments of the invention.

FIG. 2 shows a substrate processing system according to embodiments of the invention.

FIG. 3A shows a substrate processing chamber according to embodiments of the invention.

FIG. 3B shows a gas distribution showerhead according to embodiments of the invention.

### DETAILED DESCRIPTION OF THE INVENTION

Methods are described for forming and treating a flowable silicon-carbon-and-nitrogen-containing layer on a semiconductor substrate. The silicon and carbon constituents may come from a silicon-and-carbon-containing precursor while the nitrogen may come from a nitrogen-containing precursor that has been activated to speed the reaction of the nitrogen with the silicon-and-carbon-containing precursor at lower deposition temperatures. The initially-flowable silicon-carbon-and-nitrogen-containing layer is ion implanted to increase etch tolerance, prevent shrinkage, adjust film tension and/or adjust electrical characteristics. Ion implantation may also remove components which enabled the flowability, but are no longer needed after deposition. Some treatments using ion implantation have been found to decrease the evolution of properties of the film upon exposure to atmosphere.

The initial deposition of the flowable as-deposited silicon-carbon-and-nitrogen-containing layer may exhibit a high etch rate in oxide or nitride etch processes. Ion implanting the as-deposited silicon-carbon-and-nitrogen containing layer is found to decrease the etch rate as well as to provide other benefits. Without wishing to bind the claims to theoretical mechanisms which may or not be entirely correct, the inventors hypothesize that the flowability of the silicon-carbon-and-nitrogen-containing layer relates to a concentration of Si—H and C—H bonds. Fourier transform infrared spectroscopy (FTIR) has been used to suggest the presence of these bonds as well as give a rough indication of their concentration. These bonds are reactive with the moisture and other oxygen sources present in air. The removal of an as-deposited silicon-carbon-and-nitrogen-containing layer from a vacuum or other oxygen-free environment results in a slow accumulation of oxygen into the film. FTIR spectra taken at various delays after exposing as-deposited silicon-carbon-and-nitrogen-containing layers to atmosphere indicate a slow increase in prevalence of Si—O bonds and a simultaneous slow decrease in concentration of Si—H bonds. Ion implantation may decrease oxygen incorporation into the ion-implanted silicon-carbon-and-nitrogen-containing layers, decrease the etch rate of ion-implanted silicon-carbon-and-nitrogen-containing layer, and/or provide an electrical dopant within the dielectric layer.

Ion implantation of flowable as-deposited silicon-carbon-and-nitrogen-containing layers may increase the etch resistance of ion-implanted silicon-carbon-and-nitrogen-containing layers to a variety of etchants typically used to remove silicon oxide, silicon nitride and other carbon-free dielectric films. Ion implantation, therefore, may desirably improve wet-etch-rate-ratios (WERRs) for the etchants and broaden the process flows which can incorporate the ion-implanted silicon-carbon-and-nitrogen-containing layers. Ion implanted films may etch at less than or about 15 Å/min, less than or about 10 Å/min, less than or about 7 Å/min, less than or about 5 Å/min in disclosed embodiments, when exposed to typical dielectric etch chemistries. These etch rate embodiments may apply, for example, when ion implanted films are exposed to dry and wet dielectrical etches, including for example HF, buffered oxide etch, hot phosphoric acid, SC1, SC2, piranha treatments and the like.

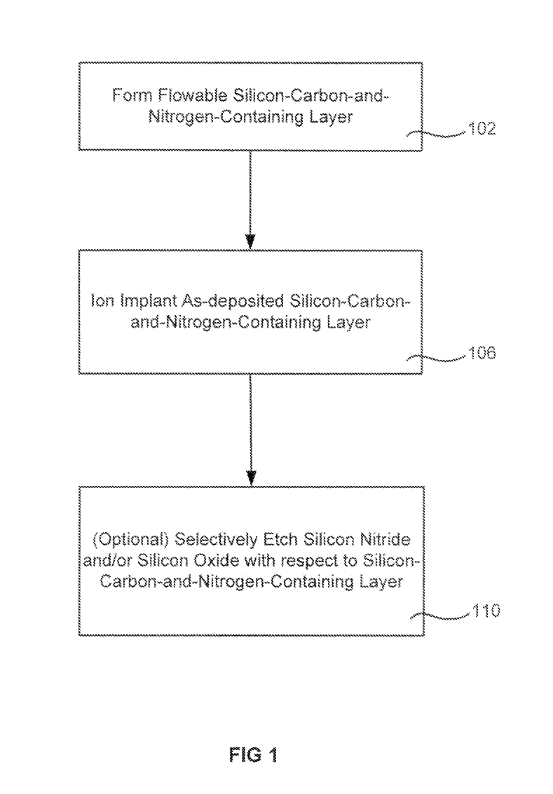

In order to better understand and appreciate the invention, reference is now made to FIG. 1 which is a flowchart showing selected steps in a method of forming a silicon-carbon-and-nitrogen-containing dielectric layer on a substrate according to embodiments of the invention. The silicon-carbon-and-nitrogen-containing layer is formed 102 on the substrate and is initially-flowable during deposition. The flowability can be a result of a variety of precursor introduction techniques, examples of which will be described herein. The origin of the flowability may be linked to the presence of hydrogen in the film, in addition to silicon, carbon and hydrogen. The hydrogen is thought to reside as Si—H and/or C—H bonds in the film which may aid in the initial flowability but also increase the etch rate of the as-deposited silicon-carbon-and-nitrogen-containing layer.

After formation of the as-deposited silicon-carbon-and-nitrogen-containing layer and optional removal of the process effluents, the as-deposited silicon-carbon-and-nitrogen-containing layer is ion implantated 106 to form an ion-implanted silicon-carbon-and-nitrogen-containing layer. The ion-implanted silicon-carbon-and-nitrogen-containing layer may have a reduced concentration of Si—H and/or C—H bonds in the layer in disclosed embodiments. A reduction in the number of these bonds may be desired after the deposition to harden the layer and increase its resistance to etching, aging, and contamination, among other forms of layer degradation. The concentration of Si—H and C—H bonds (as well as the concentration of hydrogen) may be reduced during ion implantation of the as-deposited silicon-carbon-and-nitrogen-containing layer 106 to form a ion-implanted silicon-carbon-and-nitrogen-containing layer.

Ion implantation involves impinging the as-deposited silicon-carbon-and-nitrogen with ionized species comprising a dopant. The dopant may comprise an element from a variety of groups in the periodic table, for example, the element may be from one of group III, IV or V of the periodic table. The dopant element may be one of boron, carbon, silicon or nitrogen in embodiments of the invention. Ion implantation may increase the number of Si—Si, Si—C, Si—N, and/or C—N bonds. The dopant element may be one of germanium, aluminum, phosphorus, gallium, arsenic, indium or antimony in further embodiments.

Ion implantation of the flowable as-deposited silicon-carbon-and-nitrogen-containing layer may remove the etch-promoting components of the layer adjust the stress of a tensile as-deposited film, or adjust the concentration of electrically active dopants. Ion implantation may be carried out on a completed as-deposited silicon-carbon-and-nitrogen-containing layer or implant stages may be interleaved with temporally separate partial depositions since some ion implant processes have depth penetration limits. The completed as-deposited or ion-implanted silicon-carbon-and-nitrogen-containing layer may be greater than or about 25 Å, greater than or about 100 Å, greater than or about 200 Å, greater than or about 500 Å, greater than or about 1000 Å, greater than or about 2000 Å, greater than or about 5000 Å or greater than or about 10,000 Å in embodiments of the invention, as measured in a relatively open area (having few gaps to fill). When broken up into separate depositions for interleaved ion implantation, partial as-deposited or ion-implanted silicon-carbon-and-nitrogen-containing layer may be between about 25 Å and about 1500 Å, between about 25 Å and about 1000 Å, between about 25 Å and about 500 Å, between about 25 Å and about 100 Å, or between about 25 Å and about 50 Å in disclosed embodiments. Upper or lower limits given herein may also be used separately to achieve additional disclosed embodiments.

The deposition and ion implantation may be carried out at within similar substrate temperature ranges in disclosed embodiments. For example, the substrate may be about 300° C. or less, about 250° C. or less, about 200° C. or less, about 150° C. or less, etc. The temperature of the substrate may be about −10° C. or more, about 50° C. or more, about 100° C. or more, about 125° C. or more, about 150° C. or more, etc. Upper limits may be combined with suitable lower limits to achieve additional disclosed embodiments. For example, the substrate temperature may have a range of about −10° C. to about 150° C.

Ion implanting the as-deposited silicon-carbon-and-nitrogen-containing layer may comprise exposing the layer to a high density plasma (HDP) comprising the dopant elements described above. High density plasmas allow a separate bias voltage to be applied between the ionization region and the substrate which is helpful in accelerating the dopants toward the substrate. The bias is typically a low radio-frequency and may have a bias amplitude of greater than one hundred volts, greater than two hundred volts, greater than five hundred volts or greater than one thousand volts in embodiments of the invention. The high density plasma may be formed from a gas including at least one of helium, nitrogen, argon, etc. Generally speaking, traditional ion implantation treatments may also be used and may employ accelerated ion energies that range from about 0.5 keV to about 500 keV, about 1 keV to about 200 keV or about 5 keV to about 50 keV in disclosed embodiments. The gas may be essentially devoid of oxygen in embodiments of the invention. The high density plasma may be an inductively-coupled plasma (ICP) that is generated in-situ in the deposition region of the deposition chamber. During ion implantation, the total source plasma RF power applied may be greater than or about 2000 Watts, greater than or about 3000 Watts or greater than or about 4000 Watts excluding bias power, in disclosed embodiments. Bias power is applied in some embodiments but not in others. The duration of the ion implantation may be greater than thirty seconds, greater than one minute or greater than two minutes. The pressure in the substrate processing region may be in the range from below 1 mTorr up to several Torr.

Avoiding substrate exposure to atmospheric conditions between deposition and treatment may be avoided during any of the ion implantation techniques described herein by performing deposition and ion implantation in the same chamber or the same system. Exposure to atmospheric conditions may also be avoided by transferring the substrate from one system to another in transfer pods equipped with inert gas environments.

In some embodiments, the deposition chamber may be equipped with an in-situ plasma generating system to perform plasma ion implantation in the substrate processing region of the deposition chamber. This allows the substrate to remain in the same substrate processing region for both deposition and ion implantation, enabling the substrate to avoid exposure to atmospheric conditions between deposition and implant. Alternately, the substrate may be transferred to an ion implantation unit in the same fabrication system without breaking vacuum and/or being removed from system. Ion implantation has been found to decrease or substantially eliminate etch rate for treated silicon-carbon-and-nitrogen-containing layers in standard dry and wet dielectrical etches, including for example HF, hot phosphoric acid, SC1, SC2, and piranha treatments. As a result of the effectiveness, ion implantation does not have to penetrate the whole depth of the as-deposited silicon-carbon-and-nitrogen-containing layer. For example, an as-deposited silicon-carbon-and-nitrogen-containing layer was ion implanted with carbon as dopant in a high-density plasma system. The resulting ion-implanted silicon-carbon-and-nitrogen-containing layer had an elevated carbon concentration through the first twenty five nanometers. Higher ranges for bias voltage may be used to increase the penetration depth. As used herein, a high-density-plasma process is a plasma CVD process that employs a plasma having an ion density on the order of 10¹¹ ions/cm³ or greater and has an ionization fraction (ion/neutral ratio) on the order of 10⁻⁴ or greater.

The ion-implanted silicon-carbon-and-nitrogen-containing layer may optionally be exposed to one or more etchants 110. The ion-implanted silicon-carbon-and-nitrogen-containing layer may have a wet-etch-rate-ratio (WERR) that is lower than the initially deposited flowable silicon-carbon-and-nitrogen-containing layer. A WERR may be defined as the relative etch rate of the silicon-carbon-and-nitrogen-containing layer (e.g., Å/min) in a particular etchant (e.g., dilute HF, hot phosphoric acid) compared to the etch rate of a thermally-grown silicon oxide layer formed on the same substrate. A WERR of 1.0 means the layer in question has the same etch rate as a thermal oxide layer, while a WERR of greater than 1 means the layer etches at a faster rate than thermal oxide. Ion implantation makes the deposited silicon-carbon-and-nitrogen-containing layer more resistant to etching, thus reducing its WERR in disclosed embodiments.

The ion-implanted silicon-carbon-and-nitrogen-containing layers may have increased etch resistance (i.e. a lower WERR value) to wet etchants for both silicon oxides and silicon nitrides. For example, ion implantation of the silicon-carbon-and-nitrogen-containing layer may lower the WERR level for dilute hydrofluoric acid (DHF), which is a conventional wet etchant for silicon oxide films, and may also lower the WERR level for hot phosphoric acid, which is a conventional wet etchant for silicon nitride films. Thus, the ion-implanted silicon-carbon-and-nitrogen-containing layers may make good blocking and/or etch stop layers for etch processes that include both oxide and nitride etching steps. The increased etch resistance to both conventional oxide and nitride etchants allows these silicon-carbon-and-nitrogen-containing layers to remain intact during process routines that expose the substrate to both types of etchants. The resulting increase in etch selectivity to other films increases process sequence flexibility. The ion-implanted silicon-carbon-and-nitrogen-containing layer may also have better etch resistance to a buffered oxide etch (BOE) than a silicon oxide film.

FTIR spectra taken after ion implantation indicate a reduced Si—H peak around 2250 cm¹. The presence of hydrogen in the film is likely being reduced through ion implantation. The reduction of hydrogen in the film is thought to enable the etch rate to be reduced or substantially zero in embodiments of the invention upon exposure to standard silicon oxide and silicon nitride etch chemistries. A reduction in the fine structure of FTIR spectra between 800 cm⁻¹ and 1200⁻¹ cm has also been correlated with the decrease in etch rate. Numerous sharper peaks in this band have been found to transition to one or two broad peaks and may represent replacement bonds between silicon, carbon and nitrogen as the silicon-hydrogen bonds are depleted.

### Exemplary Si—C—N Formation Methods

Forming the silicon-carbon-and-nitrogen-containing dielectric layer on a substrate may result from providing a silicon-containing precursor to a chemical vapor deposition chamber where it combines with an activated precursor (examples of which will be described herein). The silicon-containing precursor may provide the silicon constituent to the deposited silicon-carbon-and-nitrogen-containing layer, and may also provide the carbon component. Exemplary silicon-containing precursors are depicted below and may include disilacyclobutane, trisilacyclohexane, 3-methylsilane, silacyclopentene, silacyclobutane, 1,3,5-trisilapentane, and trimethylsilylacetylene, among others:

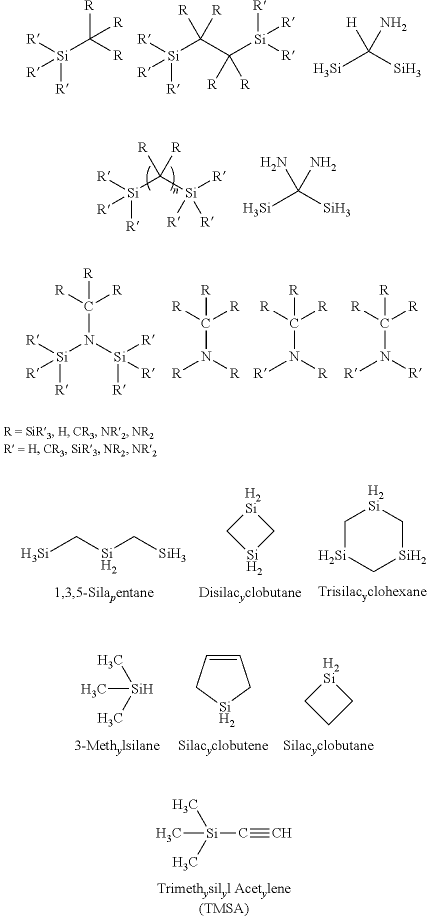

Additional exemplary silicon-containing precursors may include mono-, di-, tri-, tetra-, and penta-silanes where one or more central silicon atoms are surrounded by hydrogen and/or saturated and/or unsaturated alkyl groups. Examples of these precursors may include SiR₄, Si₂R₆, Si₃R₈, Si₄R₁₀, and Si₅R₁₂, where each R group is independently hydrogen (—H) or a saturated or unsaturated alkyl group. Specific examples of these precursors may include without limitation the following structures:

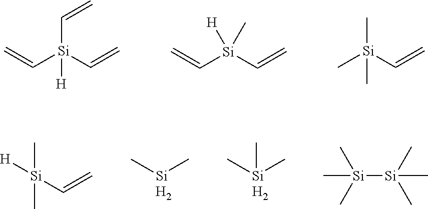

More exemplary silicon-containing precursors may include disilylalkanes having the formula R₃Si—[CR₂]ₓ—SiR₃, where each R is independently a hydrogen (—H), alkyl group (e.g., —CH₃, —CₘH₂ₘ₊₂, where m is a number from 1 to 10), unsaturated alkyl group (e.g., —CH═CH₂), and where x is a number for 0 to 10. Exemplary silicon precursors may also include trisilanes having the formula R₃Si—[CR₂]ₓ—SiR₂—[CR₂]_{y}—SiR₃, where each R is independently a hydrogen (—H), alkyl group (e.g., —CH₃, —CₘH₂ₘ₊₂, where m is a number from 1 to 10), unsaturated alkyl group (e.g., —CH═CH₂), and where x and y are independently a number from 0 to 10. Exemplary silicon-containing precursors may further include silylalkanes and silylalkenes of the form R₃Si—[CH₂]ₙ—[SiR₃]ₘ—[CH₂]ₙSiR₃, wherein n and m may be independent integers from 1 to 10, and each of the R groups are independently a hydrogen (—H), methyl (—CH₃), ethyl (—CH₂CH₃), ethylene (—CHCH₂), propyl (—CH₂CH₂CH₃), isopropyl (—CHCH₃CH₃), etc.

Exemplary silicon-containing precursors may further include polysilylalkane compounds may also include compounds with a plurality of silicon atoms that are selected from compounds with the formula R—[(CR₂)ₓ—(SiR₂)_{y}—(CR₂)_{z}]ₙ—R, wherein each R is independently a hydrogen (—H), alkyl group (e.g., —CH₃, —CₘH₂ₘ₊₂, where m is a number from 1 to 10), unsaturated alkyl group (e.g., —CH═CH₂), or silane group (e.g., —SiH₃, —(Si₂H₂)ₘ—SiH₃, where m is a number from 1 to 10)), and where x, y, and z are independently a number from 0 to 10, and n is a number from 0 to 10. In disclosed embodiments, x, y, and z are independently integers between 1 and 10 inclusive. x and z are equal in embodiments of the invention and y may equal 1 in some embodiments regardless of the equivalence of x and z. n may be 1 in some embodiments.

For example when both R groups are —SiH₃, the compounds will include polysilylalkanes having the formula H₃Si—[(CH₂)ₓ—(SiH₂)_{y}—(CH₂)_{z}]ₙ—SiH₃. The silicon-containing compounds may also include compounds having the formula R—[(CR′₂)ₓ—(SiR″₂)_{y}—(CR′₂)_{z}]ₙ—R, where each R, R′, and R″ are independently a hydrogen (—H), an alkyl group (e.g., —CH₃, —CₘH₂ₘ₊₂, where m is a number from 1 to 10), an unsaturated alkyl group (e.g., —CH═CH₂), a silane group (e.g., —SiH₃, —(Si₂H₂)ₘ—SiH₃, where m is a number from 1 to 10), and where x, y and z are independently a number from 0 to 10, and n is a number from 0 to 10. In some instances, one or more of the R′ and/or R″ groups may have the formula —[(CH₂)ₓ—(SiH₂)_{y}—(CH₂)_{z}]ₙ—R″′, wherein R″′ is a hydrogen (—H), alkyl group (e.g., —CH₃, —CₘH₂ₘ₊₂, where m is a number from 1 to 10), unsaturated alkyl group (e.g., —CH═CH₂), or silane group (e.g., —SiH₃, —(Si₂H₂)ₘ—SiH₃, where m is a number from 1 to 10)), and where x, y, and z are independently a number from 0 to 10, and n is a number from 0 to 10.

Still more exemplary silicon-containing precursors may include silylalkanes and silylalkenes such as R₃Si—[CH₂]ₙ—SiR₃, wherein n may be an integer from 1 to 10, and each of the R groups are independently a hydrogen (—H), methyl (—CH₃), ethyl (—CH₂CH₃), ethylene (—CHCH₂), propyl (—CH₂CH₂CH₃), isopropyl (—CHCH₃CH₃), etc. They may also include silacyclopropanes, silacyclobutanes, silacyclopentanes, silacyclohexanes, silacycloheptanes, silacyclooctanes, silacyclononanes, silacyclopropenes, silacyclobutenes, silacyclopentenes, silacyclohexenes, silacycloheptenes, silacyclooctenes, silacyclononenes, etc. Specific examples of these precursors may include without limitation the following structures:

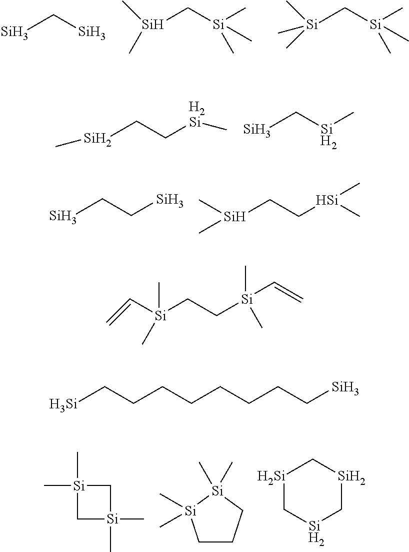

Exemplary silicon-containing precursors may further include one or more silane groups bonded to a central carbon atom or moiety. These exemplary precursors may include compounds of the formula H_{4-x-y}CX_{y}(SiR₃)ₓ, where x is 1, 2, 3, or 4, y is 0, 1, 2 or 3, each X is independently a hydrogen or halogen (e.g., F, Cl, Br), and each R is independently a hydrogen (—H) or an alkyl group. Exemplary precursors may further include compounds where the central carbon moiety is a C₂-C₆ saturated or unsaturated alkyl group such as a (SiR₃)ₓC═C(SiR₃)ₓ, where x is 1 or 2, and each R is independently a hydrogen (—H) or an alkyl group. Specific examples of these precursors may include without limitation the following structures:

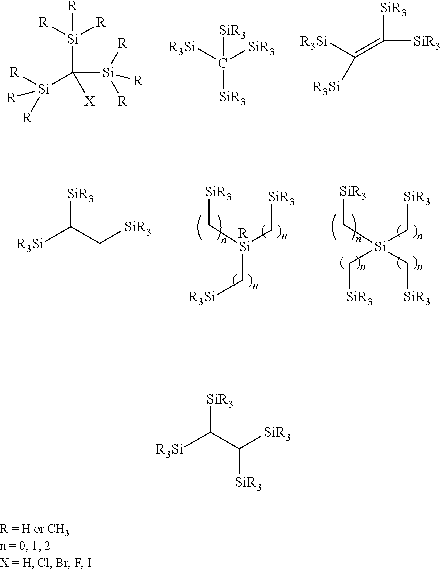

where X may be a hydrogen or a halogen (e.g., F, Cl, Br).

The silicon-containing precursors may also include nitrogen moieties. For example the precursors may include Si—N and N—Si—N moieties that are substituted or unsubstituted. For example, the precursors may include a central Si atom bonded to one or more nitrogen moieties represented by the formula R₄₋ₓSi(NR₂)ₓ, where x may be 1, 2, 3, or 4, and each R is independently a hydrogen (—H) or an alkyl group. Additional precursors may include a central N atom bonded to one or more Si-containing moieties represented by the formula R_{4-y}N(SiR₃)_{y}, where y may be 1, 2, or 3, and each R is independently a hydrogen (—H) or an alkyl group. Further examples may include cyclic compounds with Si—N and Si—N—Si groups incorporated into the ring structure. For example, the ring structure may have three (e.g., cyclopropyl), four (e.g., cyclobutyl), five (e.g., cyclopentyl), six (e.g., cyclohexyl), seven (e.g., cycloheptyl), eight (e.g., cyclooctyl), nine (e.g., cyclononyl), or more silicon and nitrogen atoms. Each atom in the ring may be bonded to one or more pendant moieties such as hydrogen (—H), an alkyl group (e.g., —CH₃), a silane (e.g., —SiR₃), an amine (—NR₂), among other groups. Specific examples of these precursors may include without limitation the following structures:

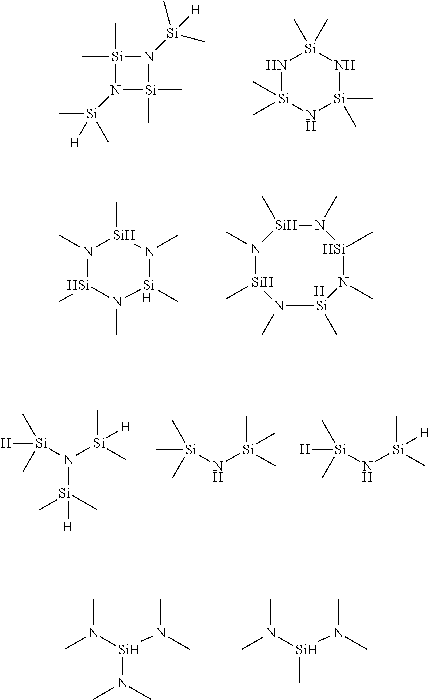

In embodiments where there is a desire to form the silicon-carbon-and-nitrogen-containing layer with low (or no) oxygen concentration, the silicon-precursor may be selected to be an oxygen-free precursor that contains no oxygen moieties. In these instances, conventional silicon CVD precursors, such as tetraethyl orthosilicate (TEOS) or tetramethyl orthosilicate (TMOS), would not be used as the silicon-containing precursor.

Additional embodiments may also include the use of a carbon-free silicon source such as silane (SiH₄), and silyl-amines (e.g., N(SiH₃)₃) among others. The source of carbon may then come from a separate precursor that is either independently provided to the deposition chamber or mixed with the silicon-containing precursor. Exemplary carbon-containing precursors may include organosilane precursors, and hydrocarbons (e.g., methane, ethane, etc.). In some instances, a silicon-and-carbon containing precursor may be combined with a carbon-free silicon precursor to adjust the silicon-to-carbon ratio in the deposited film.

Generally speaking, oxygen may or may not be present in the chamber during deposition. The presence of oxygen in the depositing film generally decreases the flowability of the film. However, some of the precursors described herein may be effectively synthesized within the chamber from silicon-and-oxygen-containing precursors. The presence of oxygen in a precursor or within the film may be tolerable as long as it does not prevent the film from providing the needed flowability. Therefore, the silicon-containing precursor may further contain oxygen and. The silicon-containing precursor may or may not react in the chamber to form silicon-and-carbon-containing precursors as described herein. The oxygen may be present in the precursor and may or may not be removed before depositing on the film surface. Exemplary oxygen-containing silicon-containing precursors may contain methoxy, ethoxy, ether, carbonyl, hydroxyl, or other Si—O, N—O, or C—O functional groups in embodiments of the invention.

In addition to the silicon-containing precursor, nitrogen-containing plasma effluents are added to the deposition chamber. The nitrogen-containing plasma effluents contribute some or all of the nitrogen constituent in the deposited silicon-carbon-and-nitrogen-containing layer. Nitrogen-containing plasma effluents are created by flowing a nitrogen-containing precursor, e.g. ammonia (NH₃), hydrazine (N₂H₄), amines, NO, N₂O, and NO₂, among others, into a remote plasma region. The nitrogen-containing precursor may be accompanied by one or more additional gases such a hydrogen (H₂), nitrogen (N₂), helium, neon, argon, etc. The nitrogen-precursor may also contain carbon that provides at least some of the carbon constituent in the deposited silicon-carbon-and-nitrogen-containing layer. Exemplary nitrogen-precursors that also contain carbon include alkyl amines. In some instances the additional gases may also be at least partially dissociated and/or radicalized by the plasma, while in other instances they may act as a dilutant/carrier gas.

The nitrogen-containing plasma effluents may be produced by a plasma formed in a remote plasma system (RPS) positioned outside the deposition chamber. The nitrogen-containing precursor may be exposed to the remote plasma where it is dissociated, radicalized, and/or otherwise transformed into the nitrogen-containing plasma effluents. For example, when the source of nitrogen-containing precursor is NH₃, nitrogen-containing plasma effluents may include one or more of .N, .NH, .NH₂, nitrogen radicals. The plasma effluents are then introduced to the deposition chamber, where they mix for the first time with the independently introduced silicon-containing precursor.

Alternatively (or in addition), the nitrogen-containing precursor may be energized in a plasma region inside the deposition chamber. This plasma region may be partitioned from the deposition region where the precursors mix and react to deposit the flowable silicon-carbon-and-nitrogen-containing layer on the exposed surfaces of the substrate. In these instances, the deposition region may be described as a “plasma free” region during the deposition process. It should be noted that “plasma free” does not necessarily mean the region is devoid of plasma. The borders of the plasma in the chamber plasma region are hard to define and may encroach upon the deposition region through, for example, the apertures of a showerhead if one is being used to transport the precursors to the deposition region. If an inductively-coupled plasma is incorporated into the deposition chamber, a small amount of ionization may be initiated in the deposition region during a deposition.

Once in the deposition chamber, the nitrogen-containing plasma effluents and the silicon-containing precursor may react to form an initially-flowable silicon-carbon-and-nitrogen-containing layer on the substrate. The temperature in the reaction region of the deposition chamber may be low (e.g., less than 100° C.) and the total chamber pressure may be about 0.1 Torr to about 10 Torr (e.g., about 0.5 to about 6 Torr, etc.) during the deposition of the silicon-carbon-and-nitrogen-containing layer. The temperature may be controlled in part by a temperature controlled pedestal that supports the substrate. The pedestal may be thermally coupled to a cooling/heating unit that adjust the pedestal and substrate temperature to, for example, about 0° C. to about 150° C.

The flowable as-deposited silicon-carbon-and-nitrogen-containing layer may be deposited on exposed planar surfaces a well as into gaps. The deposition thickness may be about 50 Å or more (e.g., about 100 Å, about 150 Å, about 200 Å, about 250 Å, about 300 Å, about 350 Å, about 400 Å, etc.). The ion-implanted silicon-carbon-and-nitrogen-containing layer may be the accumulation of two or more flowable as-deposited silicon-carbon-and-nitrogen-containing layers that have undergone ion implantation before the deposition of the subsequent layer. For example, the silicon-carbon-and-nitrogen-containing layer may be a 1200 Å thick layer consisting of four deposited and implanted 300 Å layers.

The flowability of the initially deposited silicon-carbon-and-nitrogen-containing layer may be due to a variety of properties which result from mixing the nitrogen-containing plasma effluents with the silicon-and-carbon-containing precursor. These properties may include a significant hydrogen component in the as-deposited silicon-carbon-and-nitrogen-containing layer as well as the presence of short-chained polysilazane polymers. The flowability does not rely on a high substrate temperature, therefore, the initially-flowable silicon-carbon-and-nitrogen-containing layer may fill gaps even on relatively low temperature substrates. During the formation of the silicon-carbon-and-nitrogen-containing layer, the substrate temperature may be below or about 400° C., below or about 300° C., below or about 200° C., below or about 150° C. or below or about 100° C. in embodiments of the invention.

When the flowable silicon-carbon-and-nitrogen-containing layer reaches a desired thickness, the process effluents may be removed from the deposition chamber. These process effluents may include any unreacted nitrogen-containing and silicon-containing precursors, diluent and/or carrier gases, and reaction products that did not deposit on the substrate. The process effluents may be removed by evacuating the deposition chamber and/or displacing the effluents with non-deposition gases in the deposition region.

### Exemplary Deposition Systems

Deposition chambers that may implement embodiments of the present invention may include high-density plasma chemical vapor deposition (HDP-CVD) chambers, plasma enhanced chemical vapor deposition (PECVD) chambers, sub-atmospheric chemical vapor deposition (SACVD) chambers, and thermal chemical vapor deposition chambers, among other types of chambers. Specific examples of CVD systems that may implement embodiments of the invention include the CENTURA ULTIMA® HDP-CVD chambers/systems, and PRODUCER® PECVD chambers/systems, available from Applied Materials, Inc. of Santa Clara, Calif.

Examples of substrate processing chambers that can be used with exemplary methods of the invention may include those shown and described in co-assigned U.S. Provisional Patent App. No. 60/803,499 to Lubomirsky et al, filed May 30, 2006, and titled “PROCESS CHAMBER FOR DIELECTRIC GAPFILL,” the entire contents of which is herein incorporated by reference for all purposes. Additional exemplary systems may include those shown and described in U.S. Pat. Nos. 6,387,207 and 6,830,624, which are also incorporated herein by reference for all purposes.

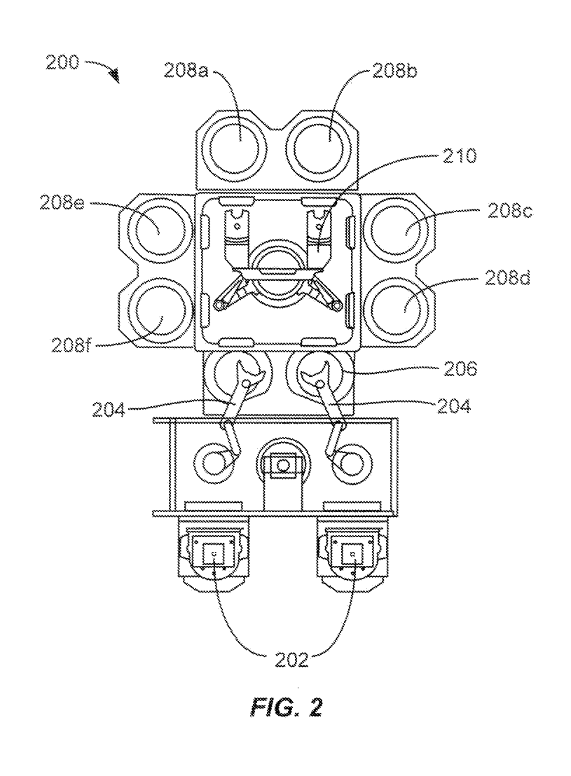

Embodiments of the deposition systems may be incorporated into larger fabrication systems for producing integrated circuit chips. FIG. 2 shows one such system 200 of deposition, baking and treating chambers according to disclosed embodiments. In the figure, a pair of FOUPs (front opening unified pods) 202 supply substrate substrates (e.g., 300 mm diameter wafers) that are received by robotic arms 204 and placed into a low pressure holding area 206 before being placed into one of the wafer processing chambers 208a-f. A second robotic arm 210 may be used to transport the substrate wafers from the holding area 206 to the processing chambers 208a-f and back.

The processing chambers 208a-f may include one or more system components for depositing, annealing, ion implanting and/or etching a flowable dielectric film on the substrate wafer. In one configuration, two pairs of the processing chamber (e.g., 208c-d and 208e-f) may be used to deposit the flowable dielectric material on the substrate, and the third pair of processing chambers (e.g., 208a-b) may be used to anneal the deposited dielectic. In another configuration, the same two pairs of processing chambers (e.g., 208c-d and 208e-f) may be configured to both deposit and anneal a flowable dielectric film on the substrate, while the third pair of chambers (e.g., 208a-b) may be used for ion implantation of the deposited film. In still another configuration, all three pairs of chambers (e.g., 208a-f) may be configured to deposit and cure a flowable dielectric film on the substrate. In yet another configuration, two pairs of processing chambers (e.g., 208c-d and 208e-f) may be used for both deposition and ion implantation of the flowable dielectric, while a third pair of processing chambers (e.g. 208a-b) may be used for annealing the dielectric film. Any one or more of the processes described may be carried out on chamber(s) separated from the fabrication system shown in different embodiments.

In addition, one or more of the process chambers 208a-f may be configured as a wet treatment chamber. These process chambers include heating the flowable dielectric film in an atmosphere that includes moisture. Thus, embodiments of system 200 may include wet treatment chambers 208a-b and anneal processing chambers 208c-d to perform both wet and dry anneals on the deposited dielectric film.

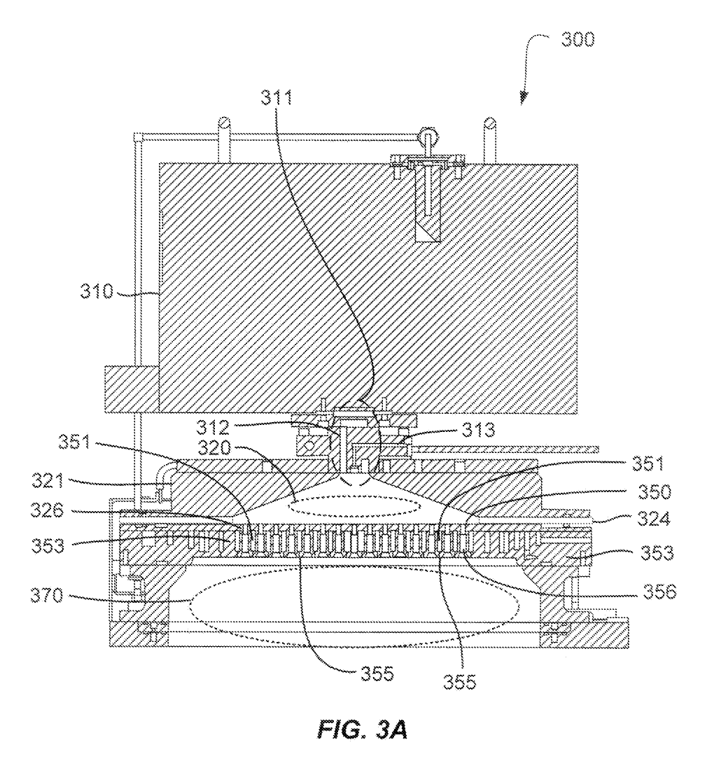

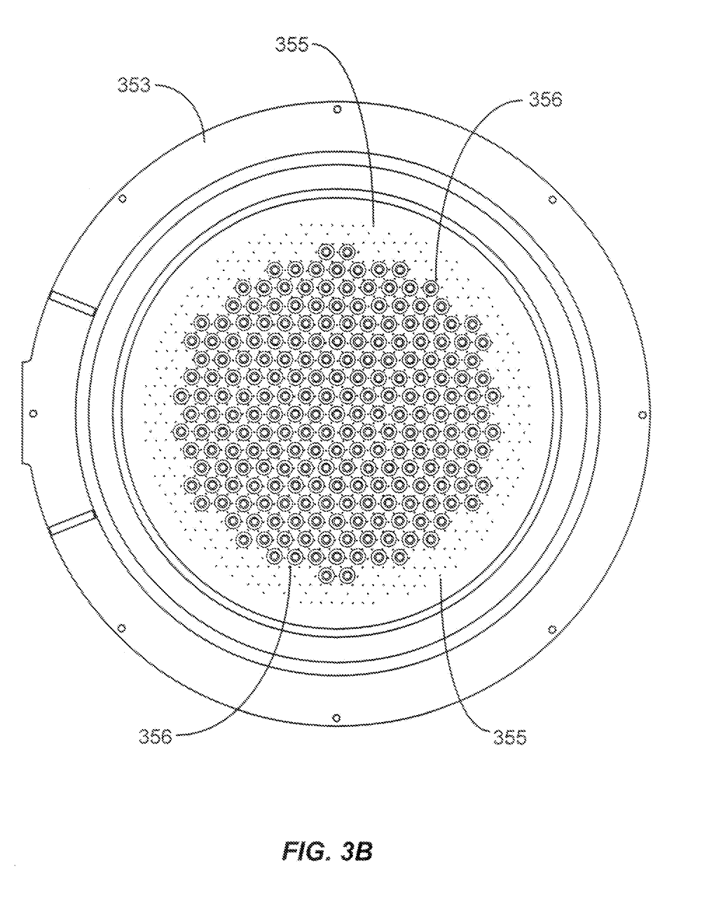

FIG. 3A is a substrate processing chamber 300 according to disclosed embodiments. A remote plasma system (RPS) 310 may process a gas which then travels through a gas inlet assembly 311. Two distinct gas supply channels are visible within the gas inlet assembly 311. A first channel 312 carries a gas that passes through the remote plasma system (RPS) 310, while a second channel 313 bypasses the RPS 310. The first channel 312 may be used for the process gas and the second channel 313 may be used for a treatment gas in disclosed embodiments. The lid (or conductive top portion) 321 and a perforated partition 353 are shown with an insulating ring 324 in between, which allows an AC potential to be applied to the lid 321 relative to perforated partition 353. The process gas travels through first channel 312 into chamber plasma region 320 and may be excited by a plasma in chamber plasma region 320 alone or in combination with RPS 310. The combination of chamber plasma region 320 and/or RPS 310 may be referred to as a remote plasma system herein. The perforated partition (also referred to as a showerhead) 353 separates chamber plasma region 320 from a substrate processing region 370 beneath showerhead 353. Showerhead 353 allows a plasma present in chamber plasma region 320 to avoid directly exciting gases in substrate processing region 370, while still allowing excited species to travel from chamber plasma region 320 into substrate processing region 370.

Showerhead 353 is positioned between chamber plasma region 320 and substrate processing region 370 and allows plasma effluents (excited derivatives of precursors or other gases) created within chamber plasma region 320 to pass through a plurality of through holes 356 that traverse the thickness of the plate. The showerhead 353 also has one or more hollow volumes 351 which can be filled with a precursor in the form of a vapor or gas (such as a silicon-containing precursor) and pass through small holes 355 into substrate processing region 370 but not directly into chamber plasma region 320. Showerhead 353 is thicker than the length of the smallest diameter 350 of the through-holes 356 in this disclosed embodiment. In order to maintain a significant concentration of excited species penetrating from chamber plasma region 320 to substrate processing region 370, the length 326 of the smallest diameter 350 of the through-holes may be restricted by forming larger diameter portions of through-holes 356 part way through the showerhead 353. The length of the smallest diameter 350 of the through-holes 356 may be the same order of magnitude as the smallest diameter of the through-holes 356 or less in disclosed embodiments.

In the embodiment shown, showerhead 353 may distribute (via through holes 356) process gases which contain hydrogen and/or nitrogen and/or plasma effluents of such process gases upon excitation by a plasma in chamber plasma region 320. Plasma effluents may include ionized or neutral derivatives of the process gas and may also be referred to herein as a radical-oxygen precursor and/or a radical-nitrogen precursor referring to the atomic constituents of the process gas introduced. During ion implantation of a silicon-carbon-and-nitrogen-containing film, process gases may be flowed into the substrate processing region 370 and a plasma may be initiated below showerhead 353 instead of above showerhead 353.

In embodiments, the number of through-holes 356 may be between about 60 and about 2000. Through-holes 356 may have a variety of shapes but are most easily made round. The smallest diameter 350 of through holes 356 may be between about 0.5 mm and about 20 mm or between about 1 mm and about 6 mm in disclosed embodiments. There is also latitude in choosing the cross-sectional shape of through-holes, which may be made conical, cylindrical or a combination of the two shapes. The number of small holes 355 used to introduce a gas into substrate processing region 370 may be between about 100 and about 5000 or between about 500 and about 2000 in different embodiments. The diameter of the small holes 355 may be between about 0.1 mm and about 2 mm.

FIG. 3B is a bottom view of a showerhead 353 for use with a processing chamber according to disclosed embodiments. Showerhead 353 corresponds with the showerhead shown in FIG. 3A. Through-holes 356 are depicted with a larger inner-diameter (ID) on the bottom of showerhead 353 and a smaller ID at the top. Small holes 355 are distributed substantially evenly over the surface of the showerhead, even amongst the through-holes 356 which helps to provide more even mixing than other embodiments described herein.

An exemplary film is created on a substrate supported by a pedestal (not shown) within substrate processing region 370 when plasma effluents arriving through through-holes 356 in showerhead 353 combine with a silicon-containing precursor arriving through the small holes 355 originating from hollow volumes 351. Though substrate processing region 370 may be equipped to support a plasma for other processes such as ion implantation, no plasma is present during the growth of the exemplary film.

A plasma may be ignited either in chamber plasma region 320 above showerhead 353 or substrate processing region 370 below showerhead 353. A plasma is present in chamber plasma region 320 to produce the radical nitrogen precursor from an inflow of a nitrogen-and-hydrogen-containing gas. An AC voltage typically in the radio frequency (RF) range is applied between the conductive top portion 321 of the processing chamber and showerhead 353 to ignite a plasma in chamber plasma region 320 during deposition. An RF power supply generates a high RF frequency of 13.56 MHz but may also generate other frequencies alone or in combination with the 13.56 MHz frequency. Radio frequencies include microwave frequencies such as 2.4 GHz. The plasma ignited below showerhead 353 in substrate processing region 370 may be a high-density plasma (HDP). The top plasma power may be greater than or about 1000 Watts, greater than or about 2000 Watts, greater than or about 3000 Watts or greater than or about 4000 Watts in embodiments of the invention, during deposition of the flowable film.

The top plasma may be left at low or no power when the bottom plasma in the substrate processing region 370 is turned on during the ion implantation stage or clean the interior surfaces bordering substrate processing region 370. A plasma in substrate processing region 370 is ignited by applying an AC voltage between showerhead 353 and the pedestal or bottom of the chamber. A cleaning gas may be introduced into substrate processing region 370 while the plasma is present.

The pedestal may have a heat exchange channel through which a heat exchange fluid flows to control the temperature of the substrate. This configuration allows the substrate temperature to be cooled or heated to maintain relatively low temperatures (from −10° C. through about 120° C.). The heat exchange fluid may comprise ethylene glycol and water. The wafer support platter of the pedestal (preferably aluminum, ceramic, or a combination thereof) may also be resistively heated in order to achieve relatively high temperatures (from about 120° C. through about 1100° C.) using an embedded single-loop embedded heater element configured to make two full turns in the form of parallel concentric circles. An outer portion of the heater element may run adjacent to a perimeter of the support platter, while an inner portion runs on the path of a concentric circle having a smaller radius. The wiring to the heater element passes through the stem of the pedestal.

The substrate processing system is controlled by a system controller. In an exemplary embodiment, the system controller includes a hard disk drive, a floppy disk drive and a processor. The processor contains a single-board computer (SBC), analog and digital input/output boards, interface boards and stepper motor controller boards. Various parts of CVD system conform to the Versa Modular European (VME) standard which defines board, card cage, and connector dimensions and types. The VME standard also defines the bus structure as having a 16-bit data bus and a 24-bit address bus.

The system controller controls all of the activities of the deposition system. The system controller executes system control software, which is a computer program stored in a computer-readable medium. Preferably, the medium is a hard disk drive, but the medium may also be other kinds of memory. The computer program includes sets of instructions that dictate the timing, mixture of gases, chamber pressure, chamber temperature, RF power levels, susceptor position, and other parameters of a particular process. Other computer programs stored on other memory devices including, for example, a floppy disk or other another appropriate drive, may also be used to instruct the system controller.

A process for depositing a film stack (e.g. sequential deposition of a silicon-carbon-and-nitrogen-containing layer and then ion implanting the layer) on a substrate or a process for cleaning a chamber can be implemented using a computer program product that is executed by the system controller. The computer program code can be written in any conventional computer readable programming language: for example, 68000 assembly language, C, C++, Pascal, Fortran or others. Suitable program code is entered into a single file, or multiple files, using a conventional text editor, and stored or embodied in a computer usable medium, such as a memory system of the computer. If the entered code text is in a high level language, the code is compiled, and the resultant compiler code is then linked with an object code of precompiled Microsoft Windows® library routines. To execute the linked, compiled object code the system user invokes the object code, causing the computer system to load the code in memory. The CPU then reads and executes the code to perform the tasks identified in the program.

The interface between a user and the controller is via a flat-panel touch-sensitive monitor. In the preferred embodiment two monitors are used, one mounted in the clean room wall for the operators and the other behind the wall for the service technicians. The two monitors may simultaneously display the same information, in which case only one accepts input at a time. To select a particular screen or function, the operator touches a designated area of the touch-sensitive monitor. The touched area changes its highlighted color, or a new menu or screen is displayed, confirming communication between the operator and the touch-sensitive monitor. Other devices, such as a keyboard, mouse, or other pointing or communication device, may be used instead of or in addition to the touch-sensitive monitor to allow the user to communicate with the system controller.

As used herein “substrate” may be a support substrate with or without layers formed thereon. The support substrate may be an insulator or a semiconductor of a variety of doping concentrations and profiles and may, for example, be a semiconductor substrate of the type used in the manufacture of integrated circuits. The term “precursor” is used to refer to any process gas which takes part in a reaction to either remove material from or deposit material onto a surface. A gas in an “excited state” describes a gas wherein at least some of the gas molecules are in vibrationally-excited, dissociated and/or ionized states. A gas (or precursor) may be a combination of two or more gases (or precursors). A “radical precursor” is used to describe plasma effluents (a gas in an excited state which is exiting a plasma) which participate in a reaction to either remove material from or deposit material on a surface. A “radical-nitrogen precursor” is a radical precursor which contains nitrogen and a “radical-hydrogen precursor” is a radical precursor which contains hydrogen. The phrase “inert gas” refers to any gas which does not form chemical bonds when etching or being incorporated into a film. Exemplary inert gases include noble gases but may include other gases so long as no chemical bonds are formed when (typically) trace amounts are trapped in a film.

The term “gap” is used throughout with no implication that the etched geometry has a large horizontal aspect ratio. Viewed from above the surface, trenches may appear circular, oval, polygonal, rectangular, or a variety of other shapes. As used herein, a conformal layer refers to a generally uniform layer of material on a surface in the same shape as the surface, i.e., the surface of the layer and the surface being covered are generally parallel. A person having ordinary skill in the art will recognize that the deposited material likely cannot be 100% conformal and thus the term “generally” allows for acceptable tolerances.

Having described several embodiments, it will be recognized by those of skill in the art that various modifications, alternative constructions, and equivalents may be used without departing from the spirit of the invention. Additionally, a number of well-known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the precursor” includes reference to one or more precursors and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

What is claimed is:

1. A method of forming a silicon-carbon-and-nitrogen-containing layer on a semiconductor substrate, the method comprising:
forming an as-deposited silicon-carbon-and-nitrogen-containing layer on the semiconductor substrate in a substrate processing region, wherein the silicon-carbon-and-nitrogen-containing layer is initially flowable during deposition; and
ion implanting the as-deposited silicon-carbon-and-nitrogen-containing layer to form an ion-implanted silicon-carbon-and-nitrogen-containing layer.

2. The method of claim 1, wherein the ion-implanted silicon-carbon-and-nitrogen-containing layer etches at a slower rate than the as-deposited silicon-carbon-and-nitrogen-containing layer in an etch solution comprising one of hydrofluoric acid or phosphoric acid.

3. The method of claim 1, wherein the as-deposited silicon-carbon-and-nitrogen-containing layer comprises Si—H bonds.

4. The method of claim 3, wherein ion implanting the as-deposited silicon-carbon-and-nitrogen-containing layer reduces the number of Si—H bonds in the material.

5. The method of claim 1, wherein the temperature of the semiconductor substrate during the ion implanting operation is about 300° C. or less.

6. The method of claim 1, wherein a thickness of the ion-implanted silicon-carbon-and-nitrogen-containing layer is greater than or about 25 Å in relatively open areas.

7. The method of claim 1, wherein a thickness of the ion-implanted silicon-carbon-and-nitrogen-containing layer is less than or about 50 Å in relatively open areas.

8. The method of claim 1, wherein the etch rate of the ion-implanted silicon-carbon-and-nitrogen-containing layer is about 15 Å/min or less in a hot phosphoric acid solution.

9. The method of claim 1, wherein the etch rate of the ion-implanted silicon-carbon-and-nitrogen-containing layer is about 15 Å/min or less in a buffered hydrofluoric acid oxide etch solution.

10. The method of claim 1, further comprising the additional subsequent steps of (1) forming a second flowable as-deposited silicon-carbon-and-nitrogen-containing layer over the ion-implanted silicon-carbon-and-nitrogen-containing layer and (2) ion implanting the second flowable as-deposited silicon-carbon-and-nitrogen-containing layer.

11. The method of claim 10, wherein a thickness of the ion-implanted second flowable as-deposited silicon-carbon-and-nitrogen-containing layer is less than or about 50 Å in relatively open areas.

12. The method of claim 1, wherein ion implanting the as-deposited silicon-carbon-and-nitrogen-containing layer is performed in the substrate processing region.

13. The method of claim 1, wherein ion implanting the as-deposited silicon-carbon-and-nitrogen-containing layer comprises exposing the material to a plasma electrically biased from the semiconductor substrate.

14. The method of claim 13, wherein the plasma for ion implanting the as-deposited silicon-carbon-and-nitrogen-containing layer is a high-density inductively-coupled plasma having an ion density greater than or about 10¹¹ ions/cm³.

15. The method of claim 13, wherein the plasma for ion implanting the as-deposited silicon-carbon-and-nitrogen-containing layer comprises an element from one of group III, IV or V of the periodic table.

16. The method of claim 13, wherein the plasma comprises an RF plasma having a total power greater than or about 2000 Watts.

17. The method of claim 1, wherein forming the as-deposited silicon-carbon-and-nitrogen-containing layer comprises:
flowing a silicon-and-carbon-containing precursor to a substrate processing region;
flowing a nitrogen-containing precursor into a remote plasma region to form plasma effluents;
flowing the plasma effluents into the substrate processing region; and
reacting the silicon-and-carbon-containing precursor and the energized nitrogen-containing precursor in the substrate processing region to form the as-deposited silicon-carbon-and-nitrogen-containing layer on the semiconductor substrate.

18. The method of claim 17, wherein the silicon-and-carbon-containing precursor comprises disilacyclobutane, trisilacyclohexane, 3-methylsilane, silacyclopentene, silacyclobutene, 1,3,5-trisilapentane, 1,4,7-trisilaheptane or trimethylsilylacetylene.

19. The method of claim 17, wherein the nitrogen-containing precursor comprises ammonia.

20. The method of claim 17, wherein the substrate processing region and the remote plasma region are compartments within a deposition chamber and the substrate processing region is separated from the substrate processing region by a showerhead.
